(19) United States
(12) Patent Application Publication
(10) Pub. No.: US 2025/0236813 A1
(43) Pub. Date: Jul. 24, 2025

(54) RINSE SOLUTION COMPOSITION FOR EXTREME ULTRAVIOLET PHOTOLITHOGRAPHY AND PATTERN FORMATION METHOD USING SAME

(71) Applicant: YCCHEM CO., LTD, Seongju-gun (KR)

(72) Inventors: Su Jin LEE, Daegu (KR); Gi Hong KIM, Daegu (KR); Seung Hun LEE, Daegu (KR); Seung Hyun LEE, Daegu (KR)

(21) Appl. No.: 19/172,684

(22) Filed: Apr. 8, 2025

Related U.S. Application Data
(63) Continuation of application No. PCT/KR2023/013621, filed on Sep. 12, 2023.

(30) Foreign Application Priority Data
Nov. 18, 2022 (KR) 10-2022-0155405

(51) Int. Cl. C11D 3/34; C11D 1/00; C11D 3/20; G03F 7/40

(52) U.S. Cl. CPC C11D 3/349; C11D 1/004; C11D 3/2065; G03F 7/40

(57) ABSTRACT

Proposed are a rinse solution composition for extreme ultraviolet photolithography and a pattern formation method using the same. The rinse solution composition includes 0.0001 to 0.01 wt % of a fluorine-based surfactant, 0.0001 to 0.5 wt % of a pattern reinforcing agent which is a compound of Formula (1), a compound of Formula (2), or a mixture thereof, 0.0001 to 0.5 wt % of a substance selected from the group consisting of a triol derivative, a tetraol derivative, and a mixture thereof, and a residual amount of water.

### TECHNICAL FIELD

The present disclosure relates to a rinse solution composition for improving a lifting defect level of a photoresist pattern during photolithography using extreme ultraviolet rays as a light source, and to a method of forming a photoresist pattern using the same.

### BACKGROUND ART

In general, semiconductors are manufactured through a lithography process using as exposure light, ultraviolet rays with in a wavelength band of 193 nm, 248 nm, or 365 nm, and there is fierce competition among semiconductor manufacturers to reduce a minimum line width (hereinafter referred to as CD: critical dimension).

In order to form a finer pattern, a light source with a narrower wavelength band is required. Currently, lithography technology using extreme ultraviolet (EUV in a wavelength of 13.5 nm) as a light sources is actively used. A finer wavelength may be realized using this lithography technology.

However, since improvements have not been made to etching resistance of an EUV photoresist, a photoresist pattern with a high aspect ratio is constantly required. This causes pattern lifting defects to easily occur during development, resulting in a problem of significantly reducing a process margin in a manufacturing process.

Accordingly, there is a need to develop a technology for alleviating the level of lifting defects that occur during formation of a fine pattern. In order to improve photoresist performance, it may be the best way to alleviate a pattern lifting defect level. However, in reality, it is difficult to develop a novel photoresist that satisfies all performance aspects.

Aside from the need for developing novel photoresists, efforts are ongoing to alleviate the pattern lifting defect level in other ways.

### DOCUMENTS OF RELATED ART

(Patent Document 1) Korean Patent No. 10-2251232;

(Patent Document 2) Korean Patent No. 10-2100432;

(Patent Document 3) Korean Patent Application Publication No. 10-2016-0117305;

(Patent Document 4) Korean Patent No. 10-2080780;

(Patent Document 5) Korean Patent No. 10-1771177;

### DISCLOSURE

### Technical Problem

An objective of the present disclosure is to provide a rinse solution composition for alleviating the level of pattern lifting defects in a pattern, the pattern lifting defects occurring after developing a photoresist, and to provide a method of forming a photoresist pattern, the method being capable of significantly reducing production costs by including a cleaning process using the rinse solution composition.

### Technical Solution

Various surfactants have been used in a water-based process solution composition that is used during a development process. However, in the present disclosure, an effective process solution composition may be prepared using a fluorine-based surfactant.

When a hydrocarbon-based surfactant with close hydrophobicity is used in a water-based process solution composition that mainly uses ultrapure water, a wall surface of a photoresist is induced to be hydrophobic, making it possible to reduce pattern melting and collapse. However, the hydrocarbon-based surfactant highly tends to agglomerate, thereby deteriorating uniformity in the properties of a rinse solution composition. Therefore, there is a possibility that the agglomerated hydrocarbon surfactant may cause defects during use of the rinse solution composition. That is, the use of the hydrocarbon-based surfactant requires an increase in its usage amount to reduce pattern melting. In this case, there is a concern that the photoresist may be damaged. In addition, when an excessive amount of unsuitable surfactant is used for the purpose of lowering surface tension of the rinse solution composition in order to reduce capillary force, it may cause pattern melting, which leads to pattern collapse.

In the present disclosure, a fluorine-based surfactant is used, and in addition, a pattern reinforcing agent which is a compound of Formula (1), a compound of Formula (2), or a mixture thereof, a substance selected from the group consisting of a triol derivative, a tetraol derivative, and a mixture thereof, and water are used. It was confirmed that the use of these materials achieved the excellent effect of alleviating a pattern lifting defect level.

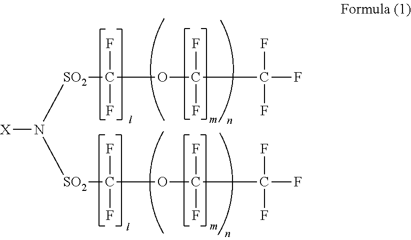

In Formula (1) above,
X is fluorine, hydrogen, or C₁ to C₅ alkyl,
X forms a single bond,
l is in the range of 1 to 4, and m and n are in the range of 1 to 3

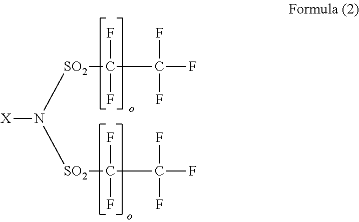

In Formula (2) above,
X is fluorine, hydrogen, or C₁ to C₅ alkyl,
X forms a single bond, and
O is in the range of 0 to 2.

As a representative developer that is currently used in most photolithography development processes, tetramethylammonium hydroxide diluted with pure water to a predetermined concentration is used (in most processes, a mixture of 2.38 wt % of tetramethylammonium hydroxide with 97.62 wt % of water is used).

It was found that pattern lifting defects occurred in the case where a photoresist pattern was successively cleaned with pure water alone after being developed in a photolithography process. In addition, it was also found that pattern collapse occurred in the case where a rinse solution composition containing tetramethylammonium hydroxide and pure water was successively applied after development or was applied continuously after the use of pure water.

In the case of the rinse solution composition containing tetramethylammonium hydroxide, it could be presumed that the pattern collapse occurred due to weakening of the exposed fine pattern and due to large or nonuniform capillary force.

Therefore, in order to reduce collapse of the exposed pattern and to reduce the line width roughness (NWR) and the number of defects in the photoresist pattern required in the process, it is necessary to conduct a study on a material that exerts a relatively weaker force on the exposed pattern than tetramethylammonium hydroxide.

In the present disclosure, a fluorine-based surfactant is used, and a pattern reinforcing agent which is a compound of Formula (1), a compound of Formula (2), or a mixture thereof, a substance selected from the group consisting of a triol derivative, a tetraol derivative, and a mixture thereof, and water are additionally used. By using these materials, it was confirmed that pattern collapse was prevented and the LWR and/or the number of defects was reduced.

According to a preferred first embodiment of the present disclosure, there is provided a rinse solution composition for alleviating a lifting defect level of a photoresist pattern during photoresist development, the rinse solution composition including: 0.0001 to 0.01 wt % of a fluorine-based surfactant; 0.0001 to 0.5 wt % of a pattern reinforcing agent which is a compound of Formula (1), a compound of Formula (2), or a mixture thereof; 0.0001 to 0.5 wt % of a substance selected from the group consisting of a triol derivative, a tetraol derivative, and a mixture thereof; and a residual amount of water.

In addition, according to a more preferred second embodiment of the present disclosure, there is provided a rinse solution composition for alleviating a lifting defect level of a photoresist pattern during photoresist development, the rinse solution composition including: 0.0001 to 0.01 wt % of a fluorine-based surfactant; 0.001 to 0.5 wt % of a pattern reinforcing agent which is a compound of Formula (1), a compound of Formula (2), or a mixture thereof; 0.0001 to 0.5 wt % of a substance selected from the group consisting of a triol derivative, a tetraol derivative, and a mixture thereof; and a residual amount of water.

Furthermore, according to a most preferred third embodiment of the present disclosure, there is provided a rinse solution composition for alleviating a lifting defect level of a photoresist pattern during photoresist development, the rinse solution composition including: 0.0001 to 0.01 wt % of a fluorine-based surfactant; 0.01 to 0.5 wt % of a pattern reinforcing agent which is a compound of Formula (1), a compound of Formula (2), or a mixture thereof; 0.0001 to 0.5 wt % of a substance selected from the group consisting of a triol derivative, a tetraol derivative, and a mixture thereof; and a residual amount of water.

In the embodiments, the fluorine-based surfactant may be selected from the group consisting of fluoroacryl carboxylate, fluoroalkyl ether, fluoroalkylene ether, fluoroalkyl sulfate, fluoroalkyl phosphate, fluoroacryl co-polymer, fluoro co-polymer, perfluorinated acid, perfluorinated carboxylate, perfluorianted sulfonate, and mixtures thereof.

In the embodiments, the triol derivative may be a C₃ to C₁₀ triol derivative selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydronaphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof.

In the embodiments, the tetraol derivative may be a C₄ to C₁₄ tetraol derivative selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof.

The present disclosure also provides a method of forming a photoresist pattern, the method including: (a) applying a photoresist to a semiconductor substrate to form a film; (b) exposing the photoresist film and then developing the photoresist film to form a pattern; and (c) cleaning the photoresist pattern with the rinse solution composition for alleviating the lifting defect level of the photoresist pattern.

The cause of pattern collapse is believed to be due to the capillary force that is generated between patterns when the pattern is cleaned with pure water after development, but the result of numerous long-term studies demonstrated that reducing only the capillary force could neither completely prevent pattern collapse and nor reduce the number of defects.

The excessive use of unsuitable surfactant for the purpose of lowering the surface tension of the rinse solution composition to reduce the capillary force may cause pattern melting, which leads to pattern lifting defects.

In order to alleviate the level of pattern lifting defects, it is important to select a surfactant that reduces the surface tension of the rinse solution composition and at the same time prevents melting of the photoresist pattern.

The rinse solution composition according to the present disclosure exhibits an excellent effect on photoresists, and particularly achieves the effect of alleviating the level of pattern lifting defects that occur during photoresist development.

### Advantageous Effects

A rinse solution composition according to the present disclosure has the effect of alleviating a lifting defect level of a pattern, the effect being unable to be achieved with a photoresist alone when forming a photoresist pattern. In particular, a method of forming a photoresist pattern including a cleaning process using the rinse solution composition has the effect of significantly reducing production costs.

### DESCRIPTION OF DRAWINGS

FIG. 1 shows the results of lifting evaluation for a photoresist pattern according to Example 1.

FIG. 2 shows the results of lifting evaluation for a photoresist pattern according to Comparative Example 1.

### BEST MODE

Hereinafter, the present disclosure will be described in more detail.

The present disclosure, which is the result of numerous long-term studies, relates to “a rinse solution composition for alleviating a lifting defect level of a photoresist pattern, the rinse solution composition including: 0.0001 to 0.01 wt % of a fluorine-based surfactant selected from the group consisting of fluoroacryl carboxylate, fluoroalkyl ether, fluoroalkylene ether, fluoroalkyl sulfate, fluoroalkyl phosphate, fluoroacryl co-polymer, fluoro co-polymer, perfluorinated acid, perfluorinated carboxylate, perfluorianted sulfonate, and mixtures thereof; 0.0001 to 0.5 wt % of a pattern reinforcing agent which is a compound of Formula (1), a compound of Formula (2), or a mixture thereof; 0.0001 to 0.5 wt % of a triol derivative alone, a tetraol derivative alone, or a mixture thereof, in which the triol derivative is a C₃ to C₁₀ triol derivative selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydronaphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof, and in which the tetraol derivative is a C₄ to C₁₄ tetraol derivative selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof; and a residual amount of water”. Composition components of the rinse solution composition according to the present disclosure and a composition ratio therebetween were specified as shown in Examples 1 to 100. Composition components and a composition ratio that were in contrast with the above-mentioned composition components and composition ratio, respectively, were specified as shown in Comparative Examples 1 to 21.

Hereinafter, preferred examples of the present disclosure and comparative examples for comparison therewith will be described. However, the following examples are merely a preferred embodiment of the present disclosure, and the present disclosure is not limited to the following examples.

### Mode for Invention

### EXAMPLE 1

A rinse solution composition for extreme ultraviolet photolithography for alleviating a collapse level of a photoresist pattern, the rinse solution composition including 0.001 wt % of fluoroacrylic carboxylate, 0.001 wt % of a fluoroimide-based compound of Formula (1), wherein l=1, m=1, and n=1, and 0.001 wt % of 1,2,3-propanetriol, was prepared by the following method. 0.001 wt % of fluoroacrylic carboxylate, 0.001 wt % of a fluoroimide-based compound of Formula (1), wherein 1=1, m=1, and n=1, and 0.001 wt % of 1,2,3-propanetriol were added into a residual amount of distilled water, stirred for 6 hours, and passed through a 0.01 μm filter to remove fine solid impurities, thereby preparing a rinse solution composition for alleviating a defect level of a photoresist pattern.

### EXAMPLE 2 TO EXAMPLE 50

Rinse solution compositions for alleviating a defect level of a photoresist pattern were prepared in the same manner as in Example 1 according to composition components and ratios that were specified as shown in Tables 1 to 12.

### EXAMPLE 51

A rinse solution composition for extreme ultraviolet photolithography for alleviating a collapse level of a photoresist pattern, the rinse solution composition including 0.001 wt % of fluoroacrylic carboxylate, 0.001 wt % of a fluoroimide-based compound of Formula (2), wherein o=1, and 0.001 wt % of 1,2,3-propanetriol, was prepared by the following method.

0.001 wt % of fluoroacrylic carboxylate, 0.001 wt % of a fluoroimide-based compound of Formula (2), wherein o=1, and 0.001 wt % of 1,2,3-propanetriol were added into a residual amount of distilled water, stirred for 6 hours, and passed through a 0.01 μm filter to remove fine solid impurities, thereby preparing a rinse solution composition for alleviating a defect level of a photoresist pattern.

### EXAMPLE 52 TO EXAMPLE 100

Rinse solution compositions for alleviating a defect level of a photoresist pattern were prepared in the same manner as in Example 51 according to composition components and ratios that were specified as shown in Tables 13 to 24.

### Comparative Example 1

Distilled water, which is generally used as the final cleaning solution in a development process during manufacture of a semiconductor device, was prepared.

### Comparative Example 2 to Comparative Example 11

For comparison with Examples, rinse solution compositions were prepared in the same manner as in Example 1, according to composition components and ratios that were specified as shown in Tables 1 to 12.

### Comparative Example 12 to Comparative Example 21

For comparison with Examples, rinse solution compositions were prepared in the same manner as in Example 51, according to composition components and ratios that were specified as shown in Tables 13 to 24.

### Experimental Example 1 to Experimental Example 100 and Comparative Experimental Example 1 to Comparative Experimental Example 21

A chemically amplified PHS acrylate hydrate hybrid EUV resist was spin-coated on a 12-inch silicon wafer (SK siltron) and soft-baked at 110° C. for 60 seconds to form a resist film with a thickness of 40 nm. The resist film on the wafer was exposed to light through 18-nm (line: space=1:1) mask in an EUV exposure apparatus. The wafer was baked (PEB) at 110° C. for 60 seconds. Then, the resist film was puddle-developed with a 2.38% tetramethylammonium hydroxide (TMAH) aqueous solution for 40 seconds. Deionized water (DI water) was poured into a puddle of developer on the wafer, the wafer was rotated while the pouring was continuing to replace the developer with the DI water, and the rotation of the wafer was stopped in a puddled state by the DI water. Subsequently, each of the rinse solution compositions of Examples 1 to 100 and Comparative Examples 2 to 21 was introduced into a puddle of DI water on the wafer, and the wafer was rotated at high speed to dry it.

At this time, pattern lifting defect level was measured for silicon wafers on which patterns were formed using the rinse solution compositions prepared in Examples 1 to 100 and Comparative Examples 1 to 21. The measurements are described as Experimental Examples 1 to 100 and Comparative Experimental Examples 1 to 21, and the results thereof are shown in Tables 25 and 26.
(1) Verification of Pattern Lifting Prevention

After exposure energy was split, among 89 total blocks, the number of blocks in which a pattern did not collapse was measured using a critical dimension-scanning electron microscope (CD-SEM, Hitachi).
(2) Transparency

Transparency of each of the prepared process solution compositions was checked with the naked eye and marked as transparent or opaque.

TABLE 1

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 1 | Fluoroacrylic | 0.001 | Compound of | 0.001 | 1,2,3- | 0.001 | Distilled | 99.9979 |
| | carboxylate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 2 | Fluoroalkyl | 0.001 | Compound of | 0.001 | 1,2,3- | 0.001 | Distilled | 99.9979 |
| | ether | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 3 | Fluoroalkylene | 0.001 | Compound of | 0.001 | 1,2,3- | 0.001 | Distilled | 99.9979 |
| | ether | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 4 | Fluoroalkyl | 0.001 | Compound of | 0.001 | 1,2,3- | 0.001 | Distilled | 99.9979 |
| | sulfate | | | | | | | |
| | | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 5 | Fluoroalkyl | 0.001 | Compound of | 0.001 | 1,2,3- | 0.001 | Distilled | 99.9979 |
| | phosphate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 6 | Fluoroacryl | 0.001 | Compound of | 0.001 | 1,2,3- | 0.001 | Distilled | 99.9979 |
| | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 7 | Fluoro | 0.001 | Compound of | 0.001 | 1,2,3- | 0.001 | Distilled | 99.9979 |
| | co-polymer | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 8 | Perfluorinated | 0.001 | Compound of | 0.001 | 1,2,3- | 0.001 | Distilled | 99.9979 |
| | acid | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 9 | Perfluorinated | 0.001 | Compound of | 0.001 | 1,2,3- | 0.001 | Distilled | 99.9979 |
| | carboxylate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 10 | Perfluorianted | 0.001 | Compound of | 0.001 | 1,2,3- | 0.001 | Distilled | 99.9979 |
| | sulfonate | | Formula | | propanetriol | | water | |
| | | | (1), | | | | | |
| | | | wherein | | | | | |
| | | | 1 = 1, m = 1, | | | | | |
| | | | and n = 1 | | | | | |
| Comparative | — | — | | | — | — | Distilled | 100 |
| Example 1 | | | | | | | water | |

TABLE 2

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 11 | Fluoroacrylic | 0.001 | Compound of | 0.001 | 1,2,3,4- | 0.001 | Distilled | 99.9979 |
| | carboxylate | | Formula | | butanetetraol | | water | |
| | | | (1), | | | | | |
| | | | wherein | | | | | |
| | | | 1 = 1, m = 1, | | | | | |
| | | | and n = 1 | | | | | |
| Example 12 | Fluoroalkyl | 0.001 | Compound of | 0.001 | 1,2,3,4- | 0.001 | Distilled | 99.9979 |
| | ether | | Formula | | butanetetraol | | water | |
| | | | (1), | | | | | |
| | | | wherein | | | | | |
| | | | 1 = 1, m = 1, | | | | | |
| | | | and n = 1 | | | | | |
| Example 13 | Fluoroalkylene | 0.001 | Compound of | 0.001 | 1,2,3,4- | 0.001 | Distilled | 99.9979 |
| | ether | | Formula | | butanetetraol | | water | |
| | | | (1), | | | | | |
| | | | wherein | | | | | |
| | | | 1 = 1, m = 1, | | | | | |
| | | | and n = 1 | | | | | |
| Example 14 | Fluoroalkyl | 0.001 | Compound of | 0.001 | 1,2,3,4- | 0.001 | Distilled | 99.9979 |
| | sulfate | | Formula | | butanetetraol | | water | |
| | | | (1), | | | | | |
| | | | wherein | | | | | |
| | | | 1 = 1, m = 1, | | | | | |
| | | | and n = 1 | | | | | |
| Example 15 | Fluoroalkyl | 0.001 | Compound of | 0.001 | 1,2,3,4- | 0.001 | Distilled | 99.9979 |
| | phosphate | | Formula | | butanetetraol | | water | |
| | | | (1), | | | | | |
| | | | wherein | | | | | |
| | | | 1 = 1, m = 1, | | | | | |
| | | | and n = 1 | | | | | |
| Example 16 | Fluoroacryl | 0.001 | Compound of | 0.001 | 1,2,3,4- | 0.001 | Distilled | 99.9979 |
| | co-polymer | | Formula | | butanetetraol | | water | |
| | | | (1), | | | | | |
| | | | wherein | | | | | |
| | | | 1 = 1, m = 1, | | | | | |
| | | | and n = 1 | | | | | |
| Example 17 | Fluoro | 0.001 | Compound of | 0.001 | 1,2,3,4- | 0.001 | Distilled | 99.9979 |
| | co-polymer | | Formula | | butanetetraol | | water | |
| | | | (1), | | | | | |
| | | | wherein | | | | | |
| | | | 1 = 1, m = 1, | | | | | |
| | | | and n = 1 | | | | | |
| Example 18 | Perfluori | 0.001 | Compoun | 0.001 | 1,2,3,4- | 0.001 | Distilled | 99.9979 |
| | nated | | d of | | butanetetr | | water | |
| | acid | | Formula | | aol | | | |
| | | | (1), | | | | | |
| | | | wherein | | | | | |
| | | | 1 = 1, m = 1, | | | | | |
| | | | and n = 1 | | | | | |
| Example 19 | Perfluorinated | 0.001 | Compound of | 0.001 | 1,2,3,4- | 0.001 | Distilled | 99.9979 |
| | carboxylate | | Formula | | butanetetraol | | water | |
| | | | (1), | | | | | |
| | | | wherein | | | | | |
| | | | 1 = 1, m = 1, | | | | | |
| | | | and n = 1 | | | | | |
| Example 20 | Perfluorianted | 0.001 | Compound of | 0.001 | 1,2,3,4- | 0.001 | Distilled | 99.9979 |
| | sulfonate | | Formula | | butanetetraol | | water | |
| | | | (1), | | | | | |
| | | | wherein | | | | | |
| | | | 1 = 1, m = 1, | | | | | |
| | | | and n = 1 | | | | | |

TABLE 3

| | Surfactant | | Pattern reinforcing | | Additive | | Distilled water | |
|---|---|---|---|---|---|---|---|---|
| | | Amount | Name | Amount | | Amount | | Amount |
| | Name | (wt %) | agent | (wt %) | Name | (wt %) | Name | (wt %) |
| Example 21 | Fluoroacrylic | 0.001 | Compound of | 0.0001 | 1,2,3- | 0.001 | Distilled | 99.9979 |
| | carboxylate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 1 | Fluoroacrylic | 0.001 | Compound of | 0.001 | 1,2,3- | 0.001 | Distilled | 99.9970 |
| | carboxylate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 22 | Fluoroacrylic | 0.001 | Compound of | 0.01 | 1,2,3- | 0.001 | Distilled | 99.9880 |
| | carboxylate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 23 | Fluoroacrylic | 0.001 | Compound of | 0.5 | 1,2,3- | 0.001 | Distilled | 99.4980 |
| | carboxylate | | Formula | | propanetriol | | water | |
| | | | (1), | | | | | |
| | | | wherein | | | | | |
| | | | 1 = 1, m = 1, | | | | | |
| | | | and n = 1 | | | | | |
| Comparative | Fluoroacrylic | 0.001 | Compound of | 1.0 | 1,2,3- | 0.001 | Distilled | 98.9980 |
| Example 2 | carboxylate | | Formula | | propanetriol | | water | |
| | | | (1), | | | | | |
| | | | wherein | | | | | |
| | | | 1 = 1, m = 1, | | | | | |
| | | | and n = 1 | | | | | |

TABLE 4

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 24 | Fluoroalkyl | 0.001 | Compound of | 0.0001 | 1,2,3- | 0.001 | Distilled | 99.9979 |
| | ether | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 2 | Fluoroalkyl | 0.001 | Compound of | 0.001 | 1,2,3- | 0.001 | Distilled | 99.9970 |
| | ether | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 25 | Fluoroalkyl | 0.001 | Compound of | 0.01 | 1,2,3- | 0.001 | Distilled | 99.9880 |
| | ether | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 26 | Fluoroalkyl | 0.001 | Compound of | 0.5 | 1,2,3- | 0.001 | Distilled | 99.4980 |
| | ether | | Formula | | propanetriol | | water | |
| | | | (1), | | | | | |
| | | | wherein | | | | | |
| | | | 1 = 1, m = 1, | | | | | |
| | | | and n = 1 | | | | | |
| Comparative | Fluoroalkyl | 0.001 | Compound of | 1.0 | 1,2,3- | 0.001 | Distilled | 98.9980 |
| Example 3 | ether | | Formula | | propanetriol | | water | |
| | | | (1), | | | | | |
| | | | wherein | | | | | |
| | | | 1 = 1, m = 1, | | | | | |
| | | | and n = 1 | | | | | |

TABLE 5

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 27 | Fluoroalkylene | 0.001 | Compound of | 0.0001 | 1,2,3- | 0.001 | Distilled | 99.9979 |
| | ether | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 3 | Fluoroalkylene | 0.001 | Compound of | 0.001 | 1,2,3- | 0.001 | Distilled | 99.9970 |
| | ether | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 28 | Fluoroalkylene | 0.001 | Compound of | 0.01 | 1,2,3- | 0.001 | Distilled | 99.9880 |
| | ether | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 29 | Fluoroalkylene | 0.001 | Compound of | 0.5 | 1,2,3- | 0.001 | Distilled | 99.4980 |
| | ether | | Formula | | propanetriol | | water | |
| | | | (1), | | | | | |
| | | | wherein | | | | | |
| | | | 1 = 1, m = 1, | | | | | |
| | | | and n = 1 | | | | | |
| Comparative | Fluoroalkylene | 0.001 | Compound of | 1.0 | 1,2,3- | 0.001 | Distilled | 98.9980 |
| Example 4 | ether | | Formula | | propanetriol | | water | |
| | | | (1), | | | | | |
| | | | wherein | | | | | |
| | | | 1 = 1, m = 1, | | | | | |
| | | | and n = 1 | | | | | |

TABLE 6

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 30 | Fluoroalkyl | 0.001 | Compound of | 0.0001 | 1,2,3- | 0.001 | Distilled | 99.9979 |
| | sulfate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 4 | Fluoroalkyl | 0.001 | Compound of | 0.001 | 1,2,3- | 0.001 | Distilled | 99.9970 |
| | sulfate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 31 | Fluoroalkyl | 0.001 | Compound of | 0.01 | 1,2,3- | 0.001 | Distilled | 99.9880 |
| | sulfate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 32 | Fluoroalkyl | 0.001 | Compound of | 0.5 | 1,2,3- | 0.001 | Distilled | 99.4980 |
| | sulfate | | Formula | | propanetriol | | water | |
| | | | (1), | | | | | |
| | | | wherein | | | | | |
| | | | 1 = 1, m = 1, | | | | | |
| | | | and n = 1 | | | | | |
| Comparative | Fluoroalkyl | 0.001 | Compound of | 1.0 | 1,2,3- | 0.001 | Distilled | 98.9980 |
| Example 5 | sulfate | | Formula | | propanetriol | | water | |
| | | | (1), | | | | | |
| | | | wherein | | | | | |
| | | | 1 = 1, m = 1, | | | | | |
| | | | and n = 1 | | | | | |

TABLE 7

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 33 | Fluoroalkyl | 0.001 | Compound of | 0.0001 | 1,2,3- | 0.001 | Distilled | 99.9979 |
| | phosphate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 5 | Fluoroalkyl | 0.001 | Compound of | 0.001 | 1,2,3- | 0.001 | Distilled | 99.9970 |
| | phosphate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 34 | Fluoroalkyl | 0.001 | Compound of | 0.01 | 1,2,3- | 0.001 | Distilled | 99.9880 |
| | phosphate | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 35 | Fluoroalkyl | 0.001 | Compound of | 0.5 | 1,2,3- | 0.001 | Distilled | 99.4980 |
| | phosphate | | Formula | | propanetriol | | water | |
| | | | (1), | | | | | |
| | | | wherein | | | | | |
| | | | 1 = 1, m = 1, | | | | | |
| | | | and n = 1 | | | | | |
| Comparative | Fluoroalkyl | 0.001 | Compound of | 1.0 | 1,2,3- | 0.001 | Distilled | 98.9980 |
| Example 6 | phosphate | | Formula | | propanetriol | | water | |
| | | | (1), | | | | | |
| | | | wherein | | | | | |
| | | | 1 = 1, m = 1, | | | | | |
| | | | and n = 1 | | | | | |

TABLE 8

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 36 | Fluoroacryl | 0.001 | Compound of | 0.0001 | 1,2,3- | 0.001 | Distilled | 99.9979 |
| | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 6 | Fluoroacryl | 0.001 | Compound of | 0.001 | 1,2,3- | 0.001 | Distilled | 99.9970 |
| | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 37 | Fluoroacryl | 0.001 | Compound of | 0.01 | 1,2,3- | 0.001 | Distilled | 99.9880 |
| | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 38 | Fluoroacryl | 0.001 | Compound of | 0.5 | 1,2,3- | 0.001 | Distilled | 99.4980 |
| | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |
| Comparative | Fluoroacryl | 0.001 | Compound of | 1.0 | 1,2,3- | 0.001 | Distilled | 98.9980 |
| Example 7 | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |

TABLE 9

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 39 | Fluoro | 0.001 | Compound of | 0.0001 | 1,2,3- | 0.001 | Distilled | 99.9979 |
| | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 7 | Fluoro | 0.001 | Compound of | 0.001 | 1,2,3- | 0.001 | Distilled | 99.9970 |
| | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 40 | Fluoro | 0.001 | Compound of | 0.01 | 1,2,3- | 0.001 | Distilled | 99.9880 |
| | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |
| Example 41 | Fluoro | 0.001 | Compound of | 0.5 | 1,2,3- | 0.001 | Distilled | 99.4980 |
| | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |
| Comparative | Fluoro | 0.001 | Compound of | 1.0 | 1,2,3- | 0.001 | Distilled | 98.9980 |
| Example 8 | copolymer | | Formula | | propanetriol | | water | |
| | | | (1), | | | | | |
| | | | wherein | | | | | |
| | | | 1 = 1, m = 1, | | | | | |
| | | | and n = 1 | | | | | |

TABLE 10

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 42 | Perfluor- | 0.001 | Compound | 0.0001 | 1,2,3- | 0.001 | Distilled | 99.9979 |
| | inated acid | | of | | pro- | | water | |
| | | | Formula | | panetriol | | | |
| | | | (1), | | | | | |
| | | | wherein | | | | | |
| | | | l = 1, m = 1, | | | | | |
| | | | and n = 1 | | | | | |
| Example 8 | Perfluor- | 0.001 | Compound | 0.001 | 1,2,3- | 0.001 | Distilled | 99.9970 |
| | inated acid | | of | | pro- | | water | |
| | | | Formula | | panetriol | | | |
| | | | (1), | | | | | |
| | | | wherein | | | | | |
| | | | l = 1, m = 1, | | | | | |
| | | | and n = 1 | | | | | |
| Example 43 | Perfluor- | 0.001 | Compound | 0.01 | 1,2,3- | 0.001 | Distilled | 99.9880 |
| | inated acid | | of | | pro- | | water | |
| | | | Formula | | panetriol | | | |
| | | | (1), | | | | | |
| | | | wherein | | | | | |
| | | | l = 1, m = 1, | | | | | |
| | | | and n = 1 | | | | | |
| Example 44 | Perfluor- | 0.001 | Compound | 0.5 | 1,2,3- | 0.001 | Distilled | 99.4980 |
| | inated acid | | of | | pro- | | water | |
| | | | Formula | | panetriol | | | |
| | | | (1), | | | | | |
| | | | wherein | | | | | |
| | | | l = 1, m = 1, | | | | | |
| | | | and n = 1 | | | | | |
| Comparative | Perfluor- | 0.001 | Compound | 1.0 | 1,2,3- | 0.001 | Distilled | 98.9980 |
| Example 9 | inated acid | | of | | pro- | | water | |
| | | | Formula | | panetriol | | | |
| | | | (1), | | | | | |
| | | | wherein | | | | | |
| | | | l = 1, m = 1, | | | | | |
| | | | and n = 1 | | | | | |

TABLE 11

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 45 | Perfluor- | 0.001 | Compound | 0.0001 | 1,2,3- | 0.001 | Distilled | 99.9979 |
| | inated | | of | | pro- | | water | |
| | carboxylate | | Formula | | panetriol | | | |
| | | | (1), | | | | | |
| | | | wherein | | | | | |
| | | | l = 1, m = 1, | | | | | |
| | | | and n = 1 | | | | | |
| Example 9 | Perfluor- | 0.001 | Compound | 0.001 | 1,2,3- | 0.001 | Distilled | 99.9970 |
| | inated | | of | | pro- | | water | |
| | carboxylate | | Formula | | panetriol | | | |
| | | | (1), | | | | | |
| | | | wherein | | | | | |
| | | | l = 1, m = 1, | | | | | |
| | | | and n = 1 | | | | | |
| Example 46 | Perfluor- | 0.001 | Compound | 0.01 | 1,2,3- | 0.001 | Distilled | 99.9880 |
| | inated | | of | | pro- | | water | |
| | carboxylate | | Formula | | panetriol | | | |
| | | | (1), | | | | | |
| | | | wherein | | | | | |
| | | | l = 1, m = 1, | | | | | |
| | | | and n = 1 | | | | | |
| Example 47 | Perfluor- | 0.001 | Compound | 0.5 | 1,2,3- | 0.001 | Distilled | 99.4980 |
| | inated | | of | | pro- | | water | |
| | carboxylate | | Formula | | panetriol | | | |
| | | | (1), | | | | | |
| | | | wherein | | | | | |
| | | | l = 1, m = 1, | | | | | |
| | | | and n = 1 | | | | | |
| Comparative | Perfluor- | 0.001 | Compound | 1.0 | 1,2,3- | 0.001 | Distilled | 98.9980 |
| Example 10 | inated | | of | | pro- | | water | |
| | carboxylate | | Formula | | panetriol | | | |
| | | | (1), | | | | | |
| | | | wherein | | | | | |
| | | | l = 1, m = 1, | | | | | |
| | | | and n = 1 | | | | | |

TABLE 12

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 48 | Perfluor- | 0.001 | Compound | 0.0001 | 1,2,3- | 0.001 | Distilled | 99.9979 |
| | ianted | | of | | pro- | | water | |
| | sulfonate | | Formula | | panetriol | | | |
| | | | (1), | | | | | |
| | | | wherein | | | | | |
| | | | l = 1, m = 1, | | | | | |
| | | | and n = 1 | | | | | |
| Example 10 | Perfluor- | 0.001 | Compound | 0.001 | 1,2,3- | 0.001 | Distilled | 99.9970 |
| | ianted | | of | | pro- | | water | |
| | sulfonate | | Formula | | panetriol | | | |
| | | | (1), | | | | | |
| | | | wherein | | | | | |
| | | | l = 1, m = 1, | | | | | |
| | | | and n = 1 | | | | | |
| Example 49 | Perfluor- | 0.001 | Compound | 0.01 | 1,2,3- | 0.001 | Distilled | 99.9880 |
| | ianted | | of | | pro- | | water | |
| | sulfonate | | Formula | | panetriol | | | |
| | | | (1), | | | | | |
| | | | wherein | | | | | |
| | | | l = 1, m = 1, | | | | | |
| | | | and n = 1 | | | | | |
| Example 50 | Perfluor- | 0.001 | Compound | 0.5 | 1,2,3- | 0.001 | Distilled | 99.4980 |
| | ianted | | of | | pro- | | water | |
| | sulfonate | | Formula | | panetriol | | | |
| | | | (1), | | | | | |
| | | | wherein | | | | | |
| | | | l = 1, m = 1, | | | | | |
| | | | and n = 1 | | | | | |
| Comparative | Perfluor- | 0.001 | Compound | 1.0 | 1,2,3- | 0.001 | Distilled | 98.9980 |
| Example 11 | ianted | | of | | pro- | | water | |
| | sulfonate | | Formula | | panetriol | | | |
| | | | (1), | | | | | |
| | | | wherein | | | | | |
| | | | l = 1, m = 1, | | | | | |
| | | | and n = 1 | | | | | |

TABLE 13

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 51 | Fluoro- | 0.001 | Compound | 0.001 | 1,2,3- | 0.001 | Distilled | 99.9979 |
| | acrylic | | of | | pro- | | water | |
| | carboxylate | | Formula | | panetriol | | | |
| | | | (2), | | | | | |
| | | | wherein | | | | | |
| | | | o = 1 | | | | | |
| Example 52 | Fluoroalkyl | 0.001 | Compound | 0.001 | 1,2,3- | 0.001 | Distilled | 99.9979 |
| | ether | | of | | pro- | | water | |
| | | | Formula | | panetriol | | | |
| | | | (2), | | | | | |
| | | | wherein | | | | | |
| | | | o = 1 | | | | | |
| Example 53 | Fluoro- | 0.001 | Compound | 0.001 | 1,2,3- | 0.001 | Distilled | 99.9979 |
| | alkylene | | of | | pro- | | water | |
| | ether | | Formula | | panetriol | | | |
| | | | (2), | | | | | |
| | | | wherein | | | | | |
| | | | o = 1 | | | | | |
| Example 54 | Fluoroalkyl | 0.001 | Compound | 0.001 | 1,2,3- | 0.001 | Distilled | 99.9979 |
| | sulfate | | of | | pro- | | water | |
| | | | Formula | | panetriol | | | |
| | | | (2), | | | | | |
| | | | wherein | | | | | |
| | | | o = 1 | | | | | |
| Example 55 | Fluoroalkyl | 0.001 | Compound | 0.001 | 1,2,3- | 0.001 | Distilled | 99.9979 |
| | phosphate | | of | | pro- | | water | |
| | | | Formula | | panetriol | | | |
| | | | (2), | | | | | |
| | | | wherein | | | | | |
| | | | o = 1 | | | | | |
| Example 56 | Fluoroacryl | 0.001 | Compound | 0.001 | 1,2,3- | 0.001 | Distilled | 99.9979 |
| | co- | | of | | pro- | | water | |
| | polymer | | Formula | | panetriol | | | |
| | | | (2), | | | | | |
| | | | wherein | | | | | |
| | | | o = 1 | | | | | |
| Example 57 | Fluoro | 0.001 | Compound | 0.001 | 1,2,3- | 0.001 | Distilled | 99.9979 |
| | co- | | of | | pro- | | water | |
| | polymer | | Formula | | panetriol | | | |
| | | | (2), | | | | | |
| | | | wherein | | | | | |
| | | | o = 1 | | | | | |
| Example 58 | Perfluor- | 0.001 | Compound | 0.001 | 1,2,3- | 0.001 | Distilled | 99.9979 |
| | inated acid | | of | | pro- | | water | |
| | | | Formula | | panetriol | | | |
| | | | (2), | | | | | |
| | | | wherein | | | | | |
| | | | o = 1 | | | | | |
| Example 59 | Perfluor- | 0.001 | Compound | 0.001 | 1,2,3- | 0.001 | Distilled | 99.9979 |
| | inated | | of | | pro- | | water | |
| | carboxylate | | Formula | | panetriol | | | |
| | | | (2), | | | | | |
| | | | wherein | | | | | |
| | | | o = 1 | | | | | |
| Example 60 | Perfluor- | 0.001 | Compound | 0.001 | 1,2,3- | 0.001 | Distilled | 99.9979 |
| | ianted | | of | | pro- | | water | |
| | sulfonate | | Formula | | panetriol | | | |
| | | | (2), | | | | | |
| | | | wherein | | | | | |
| | | | o = 1 | | | | | |
| Comparative | — | — | | | — | — | Distilled | 100 |
| Example 1 | | | | | | | water | |

TABLE 14

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 61 | Fluoro- | 0.001 | Compound | 0.001 | 1,2,3,4- | 0.001 | Distilled | 99.9979 |
| | acrylic | | of | | butane- | | water | |
| | carboxylate | | Formula | | tetraol | | | |
| | | | (2), | | | | | |
| | | | wherein | | | | | |
| | | | o = 1 | | | | | |
| Example 62 | Fluoroalkyl | 0.001 | Compound | 0.001 | 1,2,3,4- | 0.001 | Distilled | 99.9979 |
| | ether | | of | | butane- | | water | |
| | | | Formula | | tetraol | | | |
| | | | (2), | | | | | |
| | | | wherein | | | | | |
| | | | o = 1 | | | | | |
| Example 63 | Fluoro- | 0.001 | Compound | 0.001 | 1,2,3,4- | 0.001 | Distilled | 99.9979 |
| | alkylene | | of | | butane- | | water | |
| | ether | | Formula | | tetraol | | | |
| | | | (2), | | | | | |
| | | | wherein | | | | | |
| | | | o = 1 | | | | | |
| Example 64 | Fluoroalkyl | 0.001 | Compound | 0.001 | 1,2,3,4- | 0.001 | Distilled | 99.9979 |
| | sulfate | | of | | butane- | | water | |
| | | | Formula | | tetraol | | | |
| | | | (2), | | | | | |
| | | | wherein | | | | | |
| | | | o = 1 | | | | | |
| Example 65 | Fluoroalkyl | 0.001 | Compound | 0.001 | 1,2,3,4- | 0.001 | Distilled | 99.9979 |
| | phosphate | | of | | butane- | | water | |
| | | | Formula | | tetraol | | | |
| | | | (2), | | | | | |
| | | | wherein | | | | | |
| | | | o = 1 | | | | | |
| Example 66 | Fluoroacryl | 0.001 | Compound | 0.001 | 1,2,3,4- | 0.001 | Distilled | 99.9979 |
| | co- | | of | | butane- | | water | |
| | polymer | | Formula | | tetraol | | | |
| | | | (2), | | | | | |
| | | | wherein | | | | | |
| | | | o = 1 | | | | | |
| Example 67 | Fluoro | 0.001 | Compound | 0.001 | 1,2,3,4- | 0.001 | Distilled | 99.9979 |
| | co- | | of | | butane- | | water | |
| | polymer | | Formula | | tetraol | | | |
| | | | (2), | | | | | |
| | | | wherein | | | | | |
| | | | o = 1 | | | | | |
| Example 68 | Perfluor- | 0.001 | Compound | 0.001 | 1,2,3,4- | 0.001 | Distilled | 99.9979 |
| | inated acid | | of | | butane- | | water | |
| | | | Formula | | tetraol | | | |
| | | | (2), | | | | | |
| | | | wherein | | | | | |
| | | | o = 1 | | | | | |
| Example 69 | Perfluor- | 0.001 | Compound | 0.001 | 1,2,3,4- | 0.001 | Distilled | 99.9979 |
| | inated | | of | | butane- | | water | |
| | carboxylate | | Formula | | tetraol | | | |
| | | | (2), | | | | | |
| | | | wherein | | | | | |
| | | | o = 1 | | | | | |
| Example 70 | Perfluor- | 0.001 | Compound | 0.001 | 1,2,3,4- | 0.001 | Distilled | 99.9979 |
| | ianted | | of | | butane- | | water | |
| | sulfonate | | Formula | | tetraol | | | |
| | | | (2), | | | | | |
| | | | wherein | | | | | |
| | | | o = 1 | | | | | |

TABLE 15

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 71 | Fluoro- | 0.001 | Compound | 0.0001 | 1,2,3- | 0.001 | Distilled | 99.9979 |
| | acrylic | | of | | pro- | | water | |
| | carboxylate | | Formula | | panetriol | | | |
| | | | (2), | | | | | |
| | | | wherein | | | | | |
| | | | o = 1 | | | | | |
| Example 51 | Fluoro- | 0.001 | Compound | 0.001 | 1,2,3- | 0.001 | Distilled | 99.9970 |
| | acrylic | | of | | pro- | | water | |
| | carboxylate | | Formula | | panetriol | | | |
| | | | (2), | | | | | |
| | | | wherein | | | | | |
| | | | o = 1 | | | | | |
| Example 72 | Fluoro- | 0.001 | Compound | 0.01 | 1,2,3- | 0.001 | Distilled | 99.9880 |
| | acrylic | | of | | pro- | | water | |
| | carboxylate | | Formula | | panetriol | | | |
| | | | (2), | | | | | |
| | | | wherein | | | | | |
| | | | o = 1 | | | | | |
| Example 73 | Fluoro- | 0.001 | Compound | 0.5 | 1,2,3- | 0.001 | Distilled | 99.4980 |
| | acrylic | | of | | pro- | | water | |
| | carboxylate | | Formula | | panetriol | | | |
| | | | (2), | | | | | |
| | | | wherein | | | | | |
| | | | o = 1 | | | | | |
| Comparative | Fluoro- | 0.001 | Compound | 1.0 | 1,2,3- | 0.001 | Distilled | 98.9980 |
| Example 12 | acrylic | | of | | pro- | | water | |
| | carboxylate | | Formula | | panetriol | | | |
| | | | (2), | | | | | |
| | | | wherein | | | | | |
| | | | o = 1 | | | | | |

TABLE 16

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 74 | Fluoroalkyl | 0.001 | Compound | 0.0001 | 1,2,3- | 0.001 | Distilled | 99.9979 |
| | ether | | of | | pro- | | water | |
| | | | Formula | | panetriol | | | |
| | | | (2), | | | | | |
| | | | wherein | | | | | |
| | | | o = 1 | | | | | |
| Example 52 | Fluoroalkyl | 0.001 | Compound | 0.001 | 1,2,3- | 0.001 | Distilled | 99.9970 |
| | ether | | of | | pro- | | water | |
| | | | Formula | | panetriol | | | |
| | | | (2), | | | | | |
| | | | wherein | | | | | |
| | | | o = 1 | | | | | |
| Example 75 | Fluoroalkyl | 0.001 | Compound | 0.01 | 1,2,3- | 0.001 | Distilled | 99.9880 |
| | ether | | of | | pro- | | water | |
| | | | Formula | | panetriol | | | |
| | | | (2), | | | | | |
| | | | wherein | | | | | |
| | | | o = 1 | | | | | |
| Example 76 | Fluoroalkyl | 0.001 | Compound | 0.5 | 1,2,3- | 0.001 | Distilled | 99.4980 |
| | ether | | of | | pro- | | water | |
| | | | Formula | | panetriol | | | |
| | | | (2), | | | | | |
| | | | wherein | | | | | |
| | | | o = 1 | | | | | |
| Comparative | Fluoroalkyl | 0.001 | Compound | 1.0 | 1,2,3- | 0.001 | Distilled | 98.9980 |
| Example 13 | ether | | of | | pro- | | water | |
| | | | Formula | | panetriol | | | |
| | | | (2), | | | | | |
| | | | wherein | | | | | |
| | | | o = 1 | | | | | |

TABLE 17

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 77 | Fluoro- | 0.001 | Compound | 0.0001 | 1,2,3- | 0.001 | Distilled | 99.9979 |
| | alkylene | | of | | pro- | | water | |
| | ether | | Formula | | panetriol | | | |
| | | | (2), | | | | | |
| | | | wherein | | | | | |
| | | | o = 1 | | | | | |
| Example 53 | Fluoro- | 0.001 | Compound | 0.001 | 1,2,3- | 0.001 | Distilled | 99.9970 |
| | alkylene | | of | | pro- | | water | |
| | ether | | Formula | | panetriol | | | |
| | | | (2), | | | | | |
| | | | wherein | | | | | |
| | | | o = 1 | | | | | |
| Example 78 | Fluoro- | 0.001 | Compound | 0.01 | 1,2,3- | 0.001 | Distilled | 99.9880 |
| | alkylene | | of | | pro- | | water | |
| | ether | | Formula | | panetriol | | | |
| | | | (2), | | | | | |
| | | | wherein | | | | | |
| | | | o = 1 | | | | | |
| Example 79 | Fluoro- | 0.001 | Compound | 0.5 | 1,2,3- | 0.001 | Distilled | 99.4980 |
| | alkylene | | of | | pro- | | water | |
| | ether | | Formula | | panetriol | | | |
| | | | (2), | | | | | |
| | | | wherein | | | | | |
| | | | o = 1 | | | | | |
| Comparative | Fluoro- | 0.001 | Compound | 1.0 | 1,2,3- | 0.001 | Distilled | 98.9980 |
| Example 14 | alkylene | | of | | pro- | | water | |
| | ether | | Formula | | panetriol | | | |
| | | | (2), | | | | | |
| | | | wherein | | | | | |
| | | | o = 1 | | | | | |

TABLE 18

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 80 | Fluoroalkyl | 0.001 | Compound | 0.0001 | 1,2,3- | 0.001 | Distilled | 99.9979 |
| | sulfate | | of | | pro- | | water | |
| | | | Formula | | panetriol | | | |
| | | | (2), | | | | | |
| | | | wherein | | | | | |
| | | | o = 1 | | | | | |
| Example 54 | Fluoroalkyl | 0.001 | Compound | 0.001 | 1,2,3- | 0.001 | Distilled | 99.9970 |
| | sulfate | | of | | pro- | | water | |
| | | | Formula | | panetriol | | | |
| | | | (2), | | | | | |
| | | | wherein | | | | | |
| | | | o = 1 | | | | | |
| Example 81 | Fluoroalkyl | 0.001 | Compound | 0.01 | 1,2,3- | 0.001 | Distilled | 99.9880 |
| | sulfate | | of | | pro- | | water | |
| | | | Formula | | panetriol | | | |
| | | | (2), | | | | | |
| | | | wherein | | | | | |
| | | | o = 1 | | | | | |
| Example 82 | Fluoroalkyl | 0.001 | Compound | 0.5 | 1,2,3- | 0.001 | Distilled | 99.4980 |
| | sulfate | | of | | pro- | | water | |
| | | | Formula | | panetriol | | | |
| | | | (2), | | | | | |
| | | | wherein | | | | | |
| | | | o = 1 | | | | | |
| Comparative | Fluoroalkyl | 0.001 | Compound | 1.0 | 1,2,3- | 0.001 | Distilled | 98.9980 |
| Example 15 | sulfate | | of | | pro- | | water | |
| | | | Formula | | panetriol | | | |
| | | | (2), | | | | | |
| | | | wherein | | | | | |
| | | | o = 1 | | | | | |

TABLE 19

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 83 | Fluoroalkyl | 0.001 | Compound | 0.0001 | 1,2,3- | 0.001 | Distilled | 99.9979 |
| | phosphate | | of | | pro- | | water | |
| | | | Formula | | panetriol | | | |
| | | | (2), | | | | | |
| | | | wherein | | | | | |
| | | | o = 1 | | | | | |
| Example 55 | Fluoroalkyl | 0.001 | Compound | 0.001 | 1,2,3- | 0.001 | Distilled | 99.9970 |
| | phosphate | | of | | pro- | | water | |
| | | | Formula | | panetriol | | | |
| | | | (2), | | | | | |
| | | | wherein | | | | | |
| | | | o = 1 | | | | | |
| Example 84 | Fluoroalkyl | 0.001 | Compound | 0.01 | 1,2,3- | 0.001 | Distilled | 99.9880 |
| | phosphate | | of | | pro- | | water | |
| | | | Formula | | panetriol | | | |
| | | | (2), | | | | | |
| | | | wherein | | | | | |
| | | | o = 1 | | | | | |
| Example 85 | Fluoroalkyl | 0.001 | Compound | 0.5 | 1,2,3- | 0.001 | Distilled | 99.4980 |
| | phosphate | | of | | pro- | | water | |
| | | | Formula | | panetriol | | | |
| | | | (2), | | | | | |
| | | | wherein | | | | | |
| | | | o = 1 | | | | | |
| Comparative | Fluoroalkyl | 0.001 | Compound | 1.0 | 1,2,3- | 0.001 | Distilled | 98.9980 |
| Example 16 | phosphate | | of | | pro- | | water | |
| | | | Formula | | panetriol | | | |
| | | | (2), | | | | | |
| | | | wherein | | | | | |
| | | | o = 1 | | | | | |

TABLE 20

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 86 | Fluoroacryl | 0.001 | Compound | 0.0001 | 1,2,3- | 0.001 | Distilled | 99.9979 |
| | co- | | of | | pro- | | water | |
| | polymer | | Formula | | panetriol | | | |
| | | | (2), | | | | | |
| | | | wherein | | | | | |
| | | | o = 1 | | | | | |
| Example 56 | Fluoroacryl | 0.001 | Compound | 0.001 | 1,2,3- | 0.001 | Distilled | 99.9970 |
| | co- | | of | | pro- | | water | |
| | polymer | | Formula | | panetriol | | | |
| | | | (2), | | | | | |
| | | | wherein | | | | | |
| | | | o = 1 | | | | | |
| Example 87 | Fluoroacryl | 0.001 | Compound | 0.01 | 1,2,3- | 0.001 | Distilled | 99.9880 |
| | co- | | of | | pro- | | water | |
| | polymer | | Formula | | panetriol | | | |
| | | | (2), | | | | | |
| | | | wherein | | | | | |
| | | | o = 1 | | | | | |
| Example 88 | Fluoroacryl | 0.001 | Compound | 0.5 | 1,2,3- | 0.001 | Distilled | 99.4980 |
| | co- | | of | | pro- | | water | |
| | polymer | | Formula | | panetriol | | | |
| | | | (2), | | | | | |
| | | | wherein | | | | | |
| | | | o = 1 | | | | | |
| Comparative | Fluoroacryl | 0.001 | Compound | 1.0 | 1,2,3- | 0.001 | Distilled | 98.9980 |
| Example 17 | co- | | of | | pro- | | water | |
| | polymer | | Formula | | panetriol | | | |
| | | | (2), | | | | | |
| | | | wherein | | | | | |
| | | | o = 1 | | | | | |

TABLE 21

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 89 | Fluoro | 0.001 | Compound | 0.0001 | 1,2,3- | 0.001 | Distilled | 99.9979 |
| | co- | | of | | pro- | | water | |
| | polymer | | Formula | | panetriol | | | |
| | | | (2), | | | | | |
| | | | wherein | | | | | |
| | | | o = 1 | | | | | |
| Example 57 | Fluoro | 0.001 | Compound | 0.001 | 1,2,3- | 0.001 | Distilled | 99.9970 |
| | co- | | of | | pro- | | water | |
| | polymer | | Formula | | panetriol | | | |
| | | | (2), | | | | | |
| | | | wherein | | | | | |
| | | | o = 1 | | | | | |
| Example 90 | Fluoro | 0.001 | Compound | 0.01 | 1,2,3- | 0.001 | Distilled | 99.9880 |
| | co- | | of | | pro- | | water | |
| | polymer | | Formula | | panetriol | | | |
| | | | (2), | | | | | |
| | | | wherein | | | | | |
| | | | o = 1 | | | | | |
| Example 91 | Fluoro | 0.001 | Compound | 0.5 | 1,2,3- | 0.001 | Distilled | 99.4980 |
| | co- | | of | | pro- | | water | |
| | polymer | | Formula | | panetriol | | | |
| | | | (2), | | | | | |
| | | | wherein | | | | | |
| | | | o = 1 | | | | | |
| Comparative | Fluoro | 0.001 | Compound | 1.0 | 1,2,3- | 0.001 | Distilled | 98.9980 |
| Example 18 | co- | | of | | pro- | | water | |
| | polymer | | Formula | | panetriol | | | |
| | | | (2), | | | | | |
| | | | wherein | | | | | |
| | | | o = 1 | | | | | |

TABLE 22

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 92 | Perfluor- | 0.001 | Compound | 0.0001 | 1,2,3- | 0.001 | Distilled | 99.9979 |
| | inated acid | | of | | pro- | | water | |
| | | | Formula | | panetriol | | | |
| | | | (2), | | | | | |
| | | | wherein | | | | | |
| | | | o = 1 | | | | | |
| Example 58 | Perfluor- | 0.001 | Compound | 0.001 | 1,2,3- | 0.001 | Distilled | 99.9970 |
| | inated acid | | of | | pro- | | water | |
| | | | Formula | | panetriol | | | |
| | | | (2), | | | | | |
| | | | wherein | | | | | |
| | | | o = 1 | | | | | |
| Example 93 | Perfluor- | 0.001 | Compound | 0.01 | 1,2,3- | 0.001 | Distilled | 99.9880 |
| | inated acid | | of | | pro- | | water | |
| | | | Formula | | panetriol | | | |
| | | | (2), | | | | | |
| | | | wherein | | | | | |
| | | | o = 1 | | | | | |
| Example 94 | Perfluor- | 0.001 | Compound | 0.5 | 1,2,3- | 0.001 | Distilled | 99.4980 |
| | inated acid | | of | | pro- | | water | |
| | | | Formula | | panetriol | | | |
| | | | (2), | | | | | |
| | | | wherein | | | | | |
| | | | o = 1 | | | | | |
| Comparative | Perfluor- | 0.001 | Compound | 1.0 | 1,2,3- | 0.001 | Distilled | 98.9980 |
| Example 19 | inated acid | | of | | pro- | | water | |
| | | | Formula | | panetriol | | | |
| | | | (2), | | | | | |
| | | | wherein | | | | | |
| | | | o = 1 | | | | | |

TABLE 23

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 95 | Perfluor- | 0.001 | Compound | 0.0001 | 1,2,3- | 0.001 | Distilled | 99.9979 |
| | inated | | of | | pro- | | water | |
| | carboxylate | | Formula | | panetriol | | | |
| | | | (2), | | | | | |
| | | | wherein | | | | | |
| | | | o = 1 | | | | | |
| Example 59 | Perfluor- | 0.001 | Compound | 0.001 | 1,2,3- | 0.001 | Distilled | 99.9970 |
| | inated | | of | | pro- | | water | |
| | carboxylate | | Formula | | panetriol | | | |
| | | | (2), | | | | | |
| | | | wherein | | | | | |
| | | | o = 1 | | | | | |
| Example 96 | Perfluor- | 0.001 | Compound | 0.01 | 1,2,3- | 0.001 | Distilled | 99.9880 |
| | inated | | of | | pro- | | water | |
| | carboxylate | | Formula | | panetriol | | | |
| | | | (2), | | | | | |
| | | | wherein | | | | | |
| | | | o = 1 | | | | | |
| Example 97 | Perfluor- | 0.001 | Compound | 0.5 | 1,2,3- | 0.001 | Distilled | 99.4980 |
| | inated | | of | | pro- | | water | |
| | carboxylate | | Formula | | panetriol | | | |
| | | | (2), | | | | | |
| | | | wherein | | | | | |
| | | | o = 1 | | | | | |
| Comparative | Perfluor- | 0.001 | Compound | 1.0 | 1,2,3- | 0.001 | Distilled | 98.9980 |
| Example 20 | inated | | of | | pro- | | water | |
| | carboxylate | | Formula | | panetriol | | | |
| | | | (2), | | | | | |
| | | | wherein | | | | | |
| | | | o = 1 | | | | | |

TABLE 24

| | | | Pattern reinforcing | | | | | |
|---|---|---|---|---|---|---|---|---|
| | Surfactant | | agent | | Additive | | Distilled water | |
| | | Amount | | Amount | | Amount | | Amount |
| | Name | (wt %) | Name | (wt %) | Name | (wt %) | Name | (wt %) |
| Example 98 | Perfluor- | 0.001 | Compound | 0.0001 | 1,2,3- | 0.001 | Distilled | 99.9979 |
| | ianted | | of | | pro- | | water | |
| | sulfonate | | Formula | | panetriol | | | |
| | | | (2), | | | | | |
| | | | wherein | | | | | |
| | | | o = 1 | | | | | |
| Example 60 | Perfluor- | 0.001 | Compound | 0.001 | 1,2,3- | 0.001 | Distilled | 99.9970 |
| | ianted | | of | | pro- | | water | |
| | sulfonate | | Formula | | panetriol | | | |
| | | | (2), | | | | | |
| | | | wherein | | | | | |
| | | | o = 1 | | | | | |
| Example 99 | Perfluor- | 0.001 | Compound | 0.01 | 1,2,3- | 0.001 | Distilled | 99.9880 |
| | ianted | | of | | pro- | | water | |
| | sulfonate | | Formula | | panetriol | | | |
| | | | (2), | | | | | |
| | | | wherein | | | | | |
| | | | o = 1 | | | | | |
| Example 100 | Perfluor- | 0.001 | Compound | 0.5 | 1,2,3- | 0.001 | Distilled | 99.4980 |
| | ianted | | of | | pro- | | water | |
| | sulfonate | | Formula | | panetriol | | | |
| | | | (2), | | | | | |
| | | | wherein | | | | | |
| | | | o = 1 | | | | | |
| Comparative | Perfluor- | 0.001 | Compound | 1.0 | 1,2,3- | 0.001 | Distilled | 98.9980 |
| Example 21 | ianted | | of | | pro- | | water | |
| | sulfonate | | Formula | | panetriol | | | |
| | | | (2), | | | | | |
| | | | wherein | | | | | |
| | | | o = 1 | | | | | |

### Experimental Example 1 to Experimental Example 100 and Comparative Experimental Example 1 to Comparative Experimental Example 21

Pattern lifting defect level and transparency were measured for silicon wafers on which patterns were formed using the rinse solution compositions prepared in Examples 1 to 100 and Comparative Examples 1 to 21. The measurements are described as Experimental Examples 1 to 100 and Comparative Experimental Examples 1 to 21, and the results thereof are shown in Tables 25 and 26.
(1) Evaluation of Pattern Lifting Defect Level

After exposure energy was split, among 89 total blocks, the number of blocks in which a pattern did not collapse was measured using a critical dimension-scanning electron microscope (CD-SEM, Hitachi).
(2) Evaluation of Transparency

Transparency of each of the prepared rinse solution compositions was checked with the naked eye and marked as transparent or opaque.

TABLE 25

| | Number of blocks | |
|---|---|---|
| | with no pattern | |
| | lifting defect | Transparency |
| Experimental Example 1 | 58 | Transparent |
| Experimental Example 2 | 58 | Transparent |
| Experimental Example 3 | 58 | Transparent |
| Experimental Example 4 | 57 | Transparent |
| Experimental Example 5 | 57 | Transparent |
| Experimental Example 6 | 56 | Transparent |
| Experimental Example 7 | 56 | Transparent |
| Experimental Example 8 | 55 | Transparent |
| Experimental Example 9 | 54 | Transparent |
| Experimental Example 10 | 54 | Transparent |
| Experimental Example 11 | 58 | Transparent |
| Experimental Example 12 | 58 | Transparent |
| Experimental Example 13 | 57 | Transparent |
| Experimental Example 14 | 57 | Transparent |
| Experimental Example 15 | 56 | Transparent |
| Experimental Example 16 | 55 | Transparent |
| Experimental Example 17 | 55 | Transparent |
| Experimental Example 18 | 54 | Transparent |
| Experimental Example 19 | 54 | Transparent |
| Experimental Example 20 | 54 | Transparent |
| Experimental Example 21 | 57 | Transparent |
| Experimental Example 22 | 58 | Transparent |
| Experimental Example 23 | 57 | Transparent |
| Experimental Example 24 | 57 | Transparent |
| Experimental Example 25 | 58 | Transparent |
| Experimental Example 26 | 57 | Transparent |
| Experimental Example 27 | 56 | Transparent |
| Experimental Example 28 | 58 | Transparent |
| Experimental Example 29 | 57 | Transparent |
| Experimental Example 30 | 56 | Transparent |
| Experimental Example 31 | 57 | Transparent |
| Experimental Example 32 | 56 | Transparent |
| Experimental Example 33 | 56 | Transparent |
| Experimental Example 34 | 57 | Transparent |
| Experimental Example 35 | 56 | Transparent |
| Experimental Example 36 | 55 | Transparent |
| Experimental Example 37 | 56 | Transparent |
| Experimental Example 38 | 54 | Transparent |
| Experimental Example 39 | 55 | Transparent |
| Experimental Example 40 | 56 | Transparent |
| Experimental Example 41 | 54 | Transparent |
| Experimental Example 42 | 53 | Transparent |
| Experimental Example 43 | 55 | Transparent |
| Experimental Example 44 | 54 | Transparent |
| Experimental Example 45 | 53 | Transparent |
| Experimental Example 46 | 54 | Transparent |
| Experimental Example 47 | 52 | Transparent |
| Experimental Example 48 | 52 | Transparent |
| Experimental Example 49 | 54 | Transparent |
| Experimental Example 50 | 52 | Transparent |
| Comparative Experimental | 31 | Transparent |
| Example 1 | | |
| Comparative Experimental | 40 | Transparent |
| Example 2 | | |
| Comparative Experimental | 40 | Transparent |
| Example 3 | | |
| Comparative Experimental | 40 | Transparent |
| Example 4 | | |
| Comparative Experimental | 39 | Transparent |
| Example 5 | | |
| Comparative Experimental | 38 | Transparent |
| Example 6 | | |
| Comparative Experimental | 38 | Transparent |
| Example 7 | | |
| Comparative Experimental | 37 | Transparent |
| Example 8 | | |
| Comparative Experimental | 37 | Transparent |
| Example 9 | | |
| Comparative Experimental | 36 | Transparent |
| Example 10 | | |
| Comparative Experimental | 36 | Transparent |
| Example 11 | | |

TABLE 26

| | Number of blocks | |
|---|---|---|
| | with no pattern | |
| | lifting defect | Transparency |
| Experimental Example 51 | 58 | Transparent |
| Experimental Example 52 | 58 | Transparent |
| Experimental Example 53 | 57 | Transparent |
| Experimental Example 54 | 57 | Transparent |
| Experimental Example 55 | 57 | Transparent |
| Experimental Example 56 | 56 | Transparent |
| Experimental Example 57 | 55 | Transparent |
| Experimental Example 58 | 55 | Transparent |
| Experimental Example 59 | 54 | Transparent |
| Experimental Example 60 | 53 | Transparent |
| Experimental Example 61 | 57 | Transparent |
| Experimental Example 62 | 57 | Transparent |
| Experimental Example 63 | 57 | Transparent |
| Experimental Example 64 | 56 | Transparent |
| Experimental Example 65 | 56 | Transparent |
| Experimental Example 66 | 56 | Transparent |
| Experimental Example 67 | 55 | Transparent |
| Experimental Example 68 | 54 | Transparent |
| Experimental Example 69 | 54 | Transparent |
| Experimental Example 70 | 53 | Transparent |
| Experimental Example 71 | 57 | Transparent |
| Experimental Example 72 | 58 | Transparent |
| Experimental Example 73 | 56 | Transparent |
| Experimental Example 74 | 57 | Transparent |
| Experimental Example 75 | 58 | Transparent |
| Experimental Example 76 | 56 | Transparent |
| Experimental Example 77 | 56 | Transparent |
| Experimental Example 78 | 57 | Transparent |
| Experimental Example 79 | 55 | Transparent |
| Experimental Example 80 | 56 | Transparent |
| Experimental Example 81 | 57 | Transparent |
| Experimental Example 82 | 55 | Transparent |
| Experimental Example 83 | 56 | Transparent |
| Experimental Example 84 | 57 | Transparent |
| Experimental Example 85 | 54 | Transparent |
| Experimental Example 86 | 55 | Transparent |
| Experimental Example 87 | 56 | Transparent |
| Experimental Example 88 | 53 | Transparent |
| Experimental Example 89 | 54 | Transparent |
| Experimental Example 90 | 55 | Transparent |
| Experimental Example 91 | 53 | Transparent |
| Experimental Example 92 | 53 | Transparent |
| Experimental Example 93 | 55 | Transparent |
| Experimental Example 94 | 53 | Transparent |
| Experimental Example 95 | 52 | Transparent |
| Experimental Example 96 | 54 | Transparent |
| Experimental Example 97 | 52 | Transparent |
| Experimental Example 98 | 52 | Transparent |
| Experimental Example 99 | 53 | Transparent |
| Experimental Example 100 | 51 | Transparent |
| Comparative Experimental | 31 | Transparent |
| Example 1 | | |
| Comparative Experimental | 40 | Transparent |
| Example 12 | | |
| Comparative Experimental | 40 | Transparent |
| Example 13 | | |
| Comparative Experimental | 39 | Transparent |
| Example 14 | | |
| Comparative Experimental | 39 | Transparent |
| Example 15 | | |
| Comparative Experimental | 38 | Transparent |
| Example 16 | | |
| Comparative Experimental | 37 | Transparent |
| Example 17 | | |
| Comparative Experimental | 37 | Transparent |
| Example 18 | | |
| Comparative Experimental | 36 | Transparent |
| Example 19 | | |
| Comparative Experimental | 36 | Transparent |
| Example 20 | | |
| Comparative Experimental | 35 | Transparent |
| Example 21 | | |

From the comparison of Experimental Examples 1 to 100 with Comparative Experimental Examples 1 to 21 on the basis of the result of a long-term study, it was found that when the number of blocks with no pattern collapse was equal to or larger than 50 among a total of 89 blocks, a good result was obtained.

In the cases of using rinse solution compositions described below, among the rinse solution compositions corresponding to Experimental Examples 1 to 100,, in was confirmed that the pattern lifting defects were desirably reduced compared to Comparative Experimental Examples 1 to 21. The used rinse solution compositions included: 0.0001 to 0.01 wt % of a fluorine-based surfactant selected from the group consisting of fluoroacryl carboxylate, fluoroalkyl ether, fluoroalkylene ether, fluoroalkyl sulfate, fluoroalkyl phosphate, fluoroacryl co-polymer, fluoro co-polymer, perfluorinated acid, perfluorinated carboxylate, and perfluorianted sulfonate; 0.0001 to 0.5 wt % of a pattern reinforcing agent which is a compound of Formula (1), a compound of Formula (2), or a mixture thereof; 0.0001 to 0.5 wt % of a triol derivative and a tetraol derivative alone, or a mixture thereof, in which the triol derivative is a C₃ to C₁₀ triol derivative selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydronaphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof, and in which the tetraol derivative is a C4 to C14 tetraol derivative selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof; and 98.99 to 99.9997 wt % of water.

In addition, in the cases of using rinse solution compositions described below, among the rinse solution compositions corresponding to Experimental Examples 1 to 100, it was confirmed that the effect of reducing pattern lifting defects was more desirably increased compared to Comparative Experimental Examples 1 to 21. The used rinse solution compositions included: 0.0001 to 0.01 wt % of a fluorine-based surfactant selected from the group consisting of fluoroacryl carboxylate, fluoroalkyl ether, fluoroalkylene ether, fluoroalkyl sulfate, fluoroalkyl phosphate, fluoroacryl co-polymer, fluoro co-polymer, perfluorinated acid, perfluorinated carboxylate, and perfluorianted sulfonate; 0.001 to 0.5 wt % of a pattern reinforcing agent which is a compound of Formula (1), a compound of Formula (2), or a mixture thereof; 0.0001 to 0.5 wt % of a triol derivative and a tetraol derivative alone, or a mixture thereof, in which the triol derivative is a C₃ to C₁₀ triol derivative selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydronaphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof, and in which the tetraol derivative is a C₄ to C₁₄ tetraol derivative selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof; and 98.99 to 99.9988 wt % of water.

In addition, in the cases of using rinse solution compositions described below, among the rinse solution compositions corresponding to Experimental Examples 1 to 100, it was confirmed that the effect of reducing pattern lifting defects was much more desirably increased compared to Comparative Experimental Examples 1 to 21. The used rinse solution compositions included:

0.0001 to 0.01 wt % of a fluorine-based surfactant selected from the group consisting of fluoroacryl carboxylate, fluoroalkyl ether, fluoroalkylene ether, fluoroalkyl sulfate, fluoroalkyl phosphate, fluoroacryl co-polymer, fluoro co-polymer, perfluorinated acid, perfluorinated carboxylate, and perfluorianted sulfonate; 0.01 to 0.5 wt % of a pattern reinforcing agent which is a compound of Formula (1), a compound of Formula (2), or a mixture thereof; 0.0001 to 0.5 wt % of a triol derivative and a tetraol derivative alone, or a mixture thereof, in which the triol derivative is a C₃ to C₁₀ triol derivative selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydronaphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof, and in which the tetraol derivative is a C₄ to C₁₄ tetraol derivative selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof; and 98.99 to 99.9898 wt % of water.

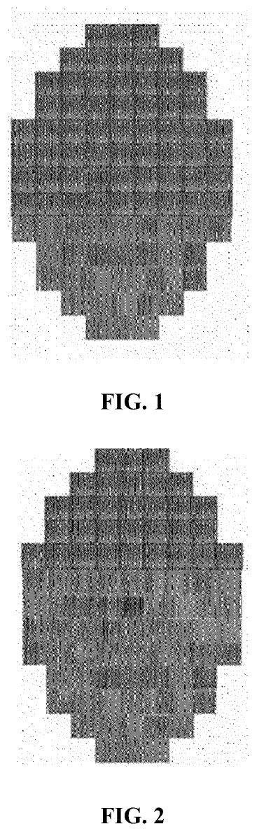

As shown in FIG. 1, the result of evaluating the collapse level of the photoresist pattern formed according to Example 1 was that the number of sections (blocks) where pattern collapse did not occur was measured to be 58, thereby having exhibited the best effect.

As shown in FIG. 2, the result of evaluating the collapse level of the photoresist pattern formed according to Comparative Experimental Example 1 was that the number of sections (blocks) where pattern collapse did not occur was measured to be 31.

Although the specific aspects of the present disclosure have been disclosed in detail above, it will be apparent to those skilled in the art to which the present disclosure pertains that this specific description is merely of preferable exemplary embodiments and is not to be construed to limit the scope of the present disclosure. Therefore, the substantial scope of the present disclosure will be defined by the appended claims and equivalents thereof.

1. A rinse solution composition for extreme ultraviolet photolithography, the rinse solution composition comprising:
a fluorine-based surfactant;
a pattern reinforcing agent which is a compound of Formula (1), a compound of Formula (2), or a mixture thereof;
a substance selected from the group consisting of a triol derivative, a tetraol derivative, and a mixture thereof; and
a residual amount of water, 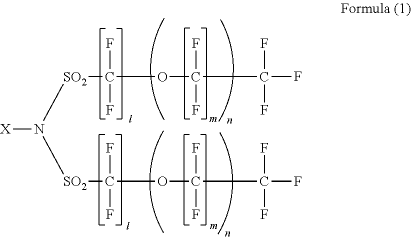
wherein, in Formula (1) above,
X is fluorine, hydrogen, or C₁ to C₅ alkyl,
X forms a single bond,
l is in a range of 1 to 4, and m and n are in a range of 1 to 3, 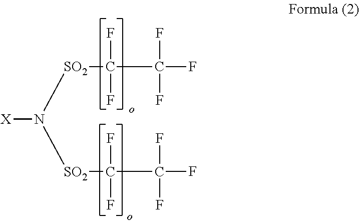
wherein, in Formula (2) above,
X is fluorine, hydrogen, or C₁ to C₅ alkyl,
X forms a single bond, and
O is in a range of 0 to 2.

2. The rinse solution composition of claim 1, comprising:
0.0001 to 0.01 wt % of a fluorine-based surfactant;
0.0001 to 0.5 wt % of a pattern reinforcing agent which is a compound of Formula (1), a compound of Formula (2), or a mixture thereof;
0.0001 to 0.5 wt % of a substance selected from the group consisting of a triol derivative, a tetraol derivative, and a mixture thereof; and
a residual amount of water.

3. The rinse solution composition of claim 2, comprising:
0.0001 to 0.01 wt % of a fluorine-based surfactant;
0.001 to 0.5 wt % of a pattern reinforcing agent which is a compound of Formula (1), a compound of Formula (2), or a mixture thereof;
0.0001 to 0.5 wt % of a substance selected from the group consisting of a triol derivative, a tetraol derivative, and a mixture thereof; and
a residual amount of water.

4. The rinse solution composition of claim 2, wherein the fluorine-based surfactant is selected from the group consisting of fluoroacryl carboxylate, fluoroalkyl ether, fluoroalkylene ether, fluoroalkyl sulfate, fluoroalkyl phosphate, fluoroacryl co-polymer, fluoro co-polymer, perfluorinated acid, perfluorinated carboxylate, perfluorianted sulfonate, and mixtures thereof.

5. The rinse solution composition of claim 2, wherein the triol derivative is a C₃ to C₁₀triol derivative selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydronaphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof, and wherein the tetraol derivative is a C₄ to C₁₄ tetraol derivative selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof.

6. A method of forming a photoresist pattern, the method comprising:
(a) applying a photoresist to a semiconductor substrate to form a film;
(b) exposing the photoresist film and then developing the photoresist film to form a pattern; and
(c) cleaning the photoresist pattern with the rinse solution composition of claim 1.
